(19) United States
(12) Patent Application Publication
(10) Pub. No.: US 2023/0238243 A1
(43) Pub. Date: Jul. 27, 2023

(54) STRUCTURE AND DEVICE INCLUDING METAL CARBON NITRIDE LAYER AND METHOD OF FORMING SAME

(71) Applicant: ASM IP Holding B.V., Almere (NL)

(72) Inventors: Mojtaba Samiee, Tempe, AZ (US); Petri Raisanen, Gilbert, AZ (US); Dong Li, Phoenix, AZ (US); Yasiel Cabrera, Phoenix, AZ (US)

(21) Appl. No.: 18/100,298

(22) Filed: Jan. 23, 2023

Related U.S. Application Data
(60) Provisional application No. 63/302,813, filed on Jan. 25, 2022.

(51) Int. Cl. H01L 21/28; H01L 29/49

(52) U.S. Cl. CPC H01L 21/28247; H01L 29/4966; H01L 21/28088

(57) ABSTRACT

Methods of forming structures including a layer of metal carbon nitride (MCN) and of mitigating metal loss from and/or tuning the layer of metal carbon nitride are disclosed. Systems for forming the layers and mitigating metal loss and structures formed using the methods are also disclosed.

### CROSS-REFERENCE TO RELATED APPLICATIONS

This application is a nonprovisional of, and claims priority to and the benefit of, U.S. Provisional Patent Application No. 63/302,813, filed Jan. 25, 2022 and entitled “METHODS FOR MITIGATING TUNGSTEN LOSS IN TUNGSTEN CARBON NITRIDE LAYERS,” which is hereby incorporated by reference herein.

### FIELD OF DISCLOSURE

The present disclosure relates generally to methods for forming structures suitable for the formation of electronic devices. More particularly, the disclosure relates to methods of forming structures including a layer of metal carbon nitride.

### BACKGROUND OF THE DISCLOSURE

The scaling of electronic devices, such as semiconductor devices, has led to significant improvements in performance and density of integrated circuits. However, conventional device scaling techniques face significant challenges for future technology nodes.

For example, one challenge has been the development of gate materials for metal-oxide-semiconductor field effect transistor (MOSFET) devices. MOSFET devices have conventionally utilized n-type doped polysilicon as the gate electrode material. However, doped polysilicon may not be an ideal gate electrode material for some applications. For example, although doped polysilicon is conductive, there may still be a surface region that can be depleted of carriers under bias conditions. This region may appear as an extra gate insulator thickness, commonly referred to as gate depletion, and may contribute to an equivalent oxide thickness. While the gate depletion region may be thin, on the order of a few angstroms (Å), it may become significant as the gate oxide thicknesses are reduced in some applications. As a further example, polysilicon does not exhibit an ideal effective work function (eWF) for both NMOS and PMOS devices. To overcome the non-ideal effective work function of doped polysilicon, a threshold voltage adjustment implantation may be utilized. However, as device geometries are reduced, the threshold voltage adjustment implantation processes may become increasingly complex and impractical.

To overcome the problems associated with doped polysilicon gate electrodes, the non-ideal doped polysilicon gate material may be replaced with an alternative material, such as a transition metal nitride. For example, a transition metal nitride may be utilized to provide a gate electrode structure with a more ideal effective work function for both the NMOS and PMOS devices, where the effective work function of the gate electrode structure, i.e., the energy needed to extract an electron, is compatible with the barrier height of the semiconductor material.

Recently, tungsten carbon nitride has been suggested as a gate metal for p-channel MOSFET devices. However, tungsten carbon nitride can suffer significant tungsten loss during post-deposition processing, which can result in reduced reliability of the MOSFET devices. Further, the as-deposited tungsten metal nitride may not exhibit desired work function values. Accordingly, methods for mitigating metal loss in and/or for tuning properties of metal carbon nitride are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of exemplary embodiments of the disclosure below. This summary is not intended to necessarily identify key features or essential features of the claimed subject matter, nor is it intended to be used to limit the scope of the claimed subject matter.

Various embodiments of the present disclosure relate to methods of forming structures including a layer comprising metal carbon nitride (MCN), to structures formed using such methods, and to systems for performing the methods and/or for forming the structures. The MCN layers can be used in a variety of applications, including use as a metal gate in MOSFET devices, and particularly as a metal gate in p-channel MOSFET devices.

In accordance with exemplary embodiments of the disclosure, a method of forming a structure comprising a layer of MCN is provided. An exemplary method includes providing a substrate within a reaction chamber, forming a deposited metal carbon nitride layer on the substrate, and tuning and/or mitigating loss of metal from the deposited metal carbon nitride layer by forming a treated metal carbon nitride surface and/or by forming a cap overlying the layer of MCN. In accordance with exemplary methods, forming the treated metal carbon nitride surface includes applying a surface treatment to the deposited metal carbon nitride layer. Forming the treated metal carbon nitride surface can be performed in-situ, i.e., within the same reactor system, module, or reaction chamber used to form the deposited MCN layer, to mitigate any undesired surface reactions prior to the step of forming the treated metal carbon nitride surface. In accordance with examples of the disclosure, applying the surface treatment includes providing an inorganic reactant to the reaction chamber. In accordance with further examples, applying the surface treatment includes providing one or more of a metal organic compound reactant and an organometallic compound reactant to the reaction chamber. In accordance with yet further examples, applying the surface treatment includes providing one or more of a halogen-containing reactant and/or activated species formed therefrom, a nitrogen-containing reactant and/or activated species formed therefrom, a carbon-containing reactant and/or activated species formed therefrom, a hydrogen-containing reactant and/or activated species formed therefrom, and a metal (e.g., titanium)-containing reactant and/or activated species formed therefrom, to the reaction chamber. In accordance with further examples, applying the surface treatment includes a plasma process. In accordance with yet further examples, applying the surface treatment includes one or more cycles of pulsing a (e.g., metal-containing) reactant to the reaction chamber. The one or more cycles can additionally include pulsing one or more of a nitrogen-containing reactant, an oxygen-containing reactant, and a carbon-containing reactant to the reaction chamber. In accordance with further examples, in addition to or in lieu of the step of forming a treated metal carbon nitride surface, the method can include a treatment step prior to the step of forming a deposited metal carbon nitride layer on the substrate.

In accordance with further exemplary embodiments of the disclosure, a structure is provided. The structure can include a substrate, a metal carbon nitride layer overlying the substrate, and a treated surface on and/or underlying the metal carbon nitride layer and/or a cap or capping layer overlying the metal carbon nitride layer. Exemplary treated surfaces can include one or more of a halogen, carbon, hydrogen, and a metal, such as titanium, aluminum, or the like. Exemplary caps or capping layers can include a metal oxide, nitride, carbide, or the like.

In accordance with further exemplary embodiments of the disclosure, a device is provided. The device can include a substrate comprising a source region, a drain region, and a channel region; a layer comprising metal carbon nitride overlying the channel region; and a treated surface overlying and/or underlying the layer comprising metal carbon nitride and/or a cap or capping layer overlying the metal carbon nitride. In accordance with examples described herein, the treated surface can include one or more of a halogen, carbon, hydrogen, and a metal, such as titanium, aluminum. Exemplary caps or capping layers can be as described above and elsewhere herein.

In accordance with yet additional examples of the disclosure, a system to perform a method as described herein and/or to form a structure, device, or a portion thereof, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a process in accordance with exemplary embodiments of the disclosure.

FIG. 3 illustrates another process in accordance with exemplary embodiments of the disclosure.

FIG. 4 illustrates a device in accordance with examples of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Moreover, recitation of multiple embodiments having stated features is not intended to exclude other embodiments having additional features or other embodiments incorporating different combinations of the stated features. Unless otherwise noted, the exemplary embodiments or components thereof may be combined in various combinations or may be applied separate from each other.

As set forth in more detail below, various embodiments of the disclosure provide methods of forming a structure comprising a layer of metal carbon nitride (MCN) on a substrate. The MCN layer may be suitable for a variety of applications, including as a barrier layer and, as described in more detail below, a gate metal. The metal in the metal carbon nitride can be a transition metal, such as, for example, tungsten (W) or molybdenum (Mo).

MCN, such as WCN and MoCN, can have many desirable properties, including relatively high work function and better scalability, compared to other materials that are typically used as gate metals. However, WCN and MoCN can undergo metal loss during subsequent processing, such as during patterning processes, and particularly during a water rinse. The loss of metal can result in undesired change and/or variation of mechanical and electrical properties of the MCN, such as undesired changes in resistivity, residual stress, thermal stability, and the like. Further, the metal loss in MCN can deleteriously affect device reliability. Examples of the disclosure mitigate metal loss from the deposited metal carbon nitride layer, thereby maintaining desired properties of the MCN and/or reducing variation of (e.g., mechanical and/or electrical) properties of the deposited MCN. Additionally, methods described herein can be used to tune properties and/or composition of the MCN.

In this disclosure, gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term precursor can refer to a compound that participates in a chemical reaction that produces another compound, and particularly to a compound that constitutes a film matrix or a main skeleton of a film; the term reactant can be used to refer to a gas that reacts with the precursor or derivative thereof to form a desired material. In some cases, the term reactant can be used interchangeably with the term precursor. The term inert gas can refer to a gas that does not take part in a chemical reaction and/or does not become a part of a film matrix to an appreciable extent. Exemplary inert gases include helium, argon, and any combination thereof.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term film and/or layer can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a structure can be or include a substrate as described herein. Structures can include features and one or more layers overlying the features, such as one or more layers formed according to a method as described herein. A device can include or be formed using a structure.

As used herein, the term cyclical deposition may refer to the sequential introduction of a precursor and a reactant into a reaction chamber to deposit a film over a substrate; the term cyclical deposition includes deposition techniques, such as atomic layer deposition (ALD) and cyclical chemical vapor deposition (CCVD).

As used herein, the term cyclical chemical vapor deposition may refer to any process wherein a substrate is sequentially exposed to a precursor and a reactant, which react and/or decompose on a substrate to deposit a desired film. In some cases, one of the precursor and the reactant can be pulsed to the reaction chamber and the other of the precursor and the reactant can be continuously flowed to the substrate during one or more cycles of the cyclical chemical vapor deposition process.

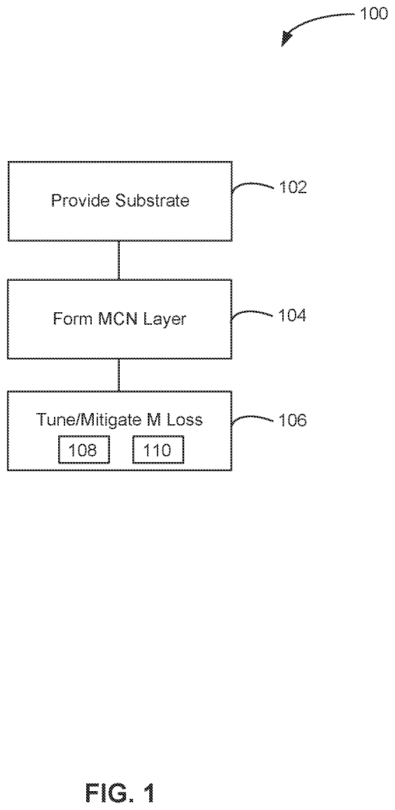

Turning now to FIG. 1, a method 100 in accordance with examples of the disclosure is illustrated. Method 100 includes the steps of providing a substrate within a reaction chamber (102), forming a deposited metal carbon nitride layer on the substrate (step 104), and tuning/mitigating loss of metal from the deposited metal carbon nitride layer (step 106).

During step 102, a substrate is provided within a reaction chamber. The substrate can include any substrate as described herein. By way of particular examples, the substrate can be suitable for formation of metal-oxide-semiconductor (MOS) devices, such as PMOS and CMOS devices.

The reaction chamber used during step 102 can be or include a reaction chamber of a chemical vapor deposition reactor system configured to perform a deposition process. The reaction chamber can be a standalone reaction chamber or part of a cluster tool or module.

Step 102 can include heating the substrate to a desired deposition temperature within the reaction chamber. In some embodiments of the disclosure, step 102 includes heating the substrate to a temperature of less than 450° C. For example, in some embodiments of the disclosure, heating the substrate to a deposition temperature may comprise heating the substrate to a temperature between approximately 20° C. and approximately 350° C., between about 350° C. and 400° C., or between about 400° C. and 450° C.

In addition to controlling the temperature of the substrate, a pressure within the reaction chamber may also be regulated. For example, in some embodiments of the disclosure, the pressure within the reaction chamber during step 102 may be less than 760 torr or between about 0.2 torr and 760 torr.

Step 104 can include a typical chemical vapor deposition (CVD) process or a cyclical process, such as an ALD or a CCVD process. In accordance with exemplary methods, step 104 is a thermal process—i.e., a plasma is not used to form excited species during the step.

During step 104, a precursor and a reactant can be introduced into the reaction chamber. In the case of cyclical processes, the introduction of the precursor and the reactant can be alternating, sequential and separated by a purge step, or one of the precursor and the reactant can be pulsed to the reaction chamber, while the other of the precursor and the reactant is continually flowed to the reaction chamber.

A purge step can be effected either in time or in space, or both. For example, in the case of temporal purges, a purge step can be used, e.g., in the temporal sequence of providing a precursor to a reaction chamber, providing a purge gas to the reaction chamber, and providing a reactant to the reaction chamber, wherein the substrate on which a material is deposited does not move. In the case of spatial purges, a purge step can take the following form: moving a substrate from a first location to which a first precursor is (e.g., continually) supplied, through a purge gas curtain, to a second location to which a second precursor is (e.g., continually) supplied. Purging times may be, for example, from about 0.01 seconds to about 20 seconds, from about 0.05 seconds to about 20 seconds, or from about 1 seconds to about 20 seconds, or from about 0.5 seconds to about 10 seconds, or between about 1 seconds and about 7 seconds.

A precursor used to form the deposited metal carbon nitride layer on the substrate can include a tungsten- or molybdenum-containing precursor, such as one or more precursors selected from the group consisting of fluorine free tungsten or molybdenum metal-organic precursors. In some cases, the tungsten or molybdenum precursor includes carbon.

A reactant used to form the deposited metal carbon nitride layer on the substrate can include a nitrogen-containing reactant, such as one or more reactants selected from the group consisting of NH₃, N₂/H₂ and/or hydrazine. In some cases, the nitrogen precursor can also include carbon.

A thickness of the deposited metal carbon nitride layer can range from about 1 to about 20 or about 0.5 to about 10 nm. A composition of the deposited metal carbon nitride layer can include about 1 to about 65 or about 0.5 to about 70 at % metal (e.g., tungsten or molybdenum), about 0 to about 20 or about 1 to about 10 at % carbon, and/or about 0 to about 35 or about 1 to about 30 at % nitrogen.

Mitigation of metal loss from the deposited metal carbon nitride layer can be performed during step 106. Mitigating loss of metal step 106 can include applying a surface treatment (step 108) and/or forming a cap or capping layer (step 110). Additionally or alternatively, properties of the metal carbide layer can be tuned during step 106. When used to tune properties, step 106 can be performed before and/or after step 104.

As noted above, in accordance with examples of the disclosure, step 106 can be performed within the same reactor system, the same module, or the same reaction chamber used during steps 102 and 104. A pressure and/or temperature can be as noted above.

As set forth in more detail below, in accordance with examples of the disclosure, step 106 can include providing an inorganic reactant, such as a metal halide or a nitrogen-containing reactant, or the like, to the reaction chamber, or an organic precursor, such as those noted below.

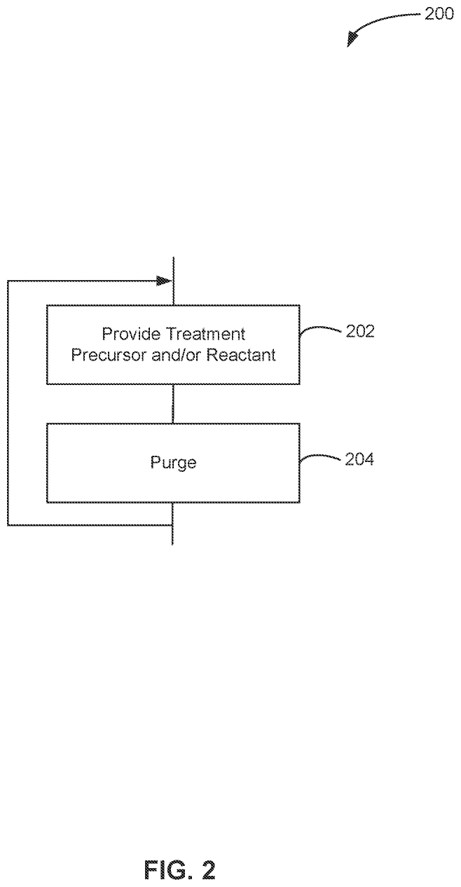

FIG. 2 illustrates a process 200 suitable for use as step 108/106 in accordance with examples of the disclosure. Process 200 includes providing a treatment precursor and/or reactant (step 202) and a purge (step 204). Process 200 can be a thermal process, where a plasma is not used to form excited species. In other cases, process 200 can include forming excited species using, for example, a direct, indirect, or remote plasma.

Step 202 can include pulsing a reactant and/or precursor to the reaction chamber or a single flow of the reactant and/or precursor. A duration of one or more pulses can be between about 1 and about 60 or between about 0.5 and about 100 seconds. A flowrate of the reactant/precursor can be between about 100 and about 2000 sccm. In some cases, process 200 can include flowing a single precursor or reactant to effect a surface treatment.

Step 204 can be the same or similar to the purge step described above. As illustrated, steps 202 and 204 can be repeated a number (e.g., about 0 or 1 to about 10 or about 1 to about 20) of times to obtain a desired treatment.

Alternatively, as noted above, step 202 can include a continuous flow of the reactant and/or precursor to the reaction chamber, which can be followed by a single purge (step 204). In accordance with further examples, step 202 can include a soak process. In such cases, a valve downstream of the reaction chamber may be closed or at least further restricted, such that the precursor and/or reactant remain within the reaction chamber for an extended period of time. In some cases, the precursor and/or reactant may continue to flow during the soak period. Further, in some cases, a pressure within the reaction chamber can increase during the soak period.

In accordance with examples of the disclosure, step 108/202 includes providing one or more of a halogen-containing reactant and/or activated species formed therefrom, a nitrogen-containing reactant and/or activated species formed therefrom, a carbon-containing reactant and/or activated species formed therefrom, a hydrogen-containing reactant and/or activated species formed therefrom, and a metal (e.g., titanium)-containing reactant and/or activated species formed therefrom, to the reaction chamber. When excited species are provided to the reaction chamber, the excited species can be formed using, for example, a remote plasma. Additionally or alternatively, excited species can be formed using a direct and/or indirect plasma within the reaction chamber.

Exemplary halogen-containing reactants include metal-halogen compounds, such as metal chloride, bromide, or iodide compounds. By way of examples, the halogen-containing reactant can include group IV or group III metal compounds, such as titanium tetrachloride, aluminum chloride.

Exemplary nitrogen-containing reactants include, for example, nitrogen, a mixture of nitrogen and hydrogen (e.g., about 1 to about 10 or about 10 to about 50 vol % hydrogen), hydrazine, a derivative thereof—e.g., where each of the one to four substituents can be independently selected from H and a C1-C4 alkyl group. Particular examples of hydrazine derivatives include alkylhydrazines, dialkylhydrazines, such as tertbutylhydrazine (C₄H₉N₂H₃), methylhydrazine (CH₃NHNH₂), 1,1-dimethylhydrazine ((CH₃)₂N₂H₂), 1,2-dimethylhydrazine, ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, and azo-tert-butane. The nitrogen-containing reactant can be used to create excited species that can be used to densify a top layer/surface of the deposited metal carbon nitride layer. The densification can result in removal of carbon from the surface, resulting in metal (e.g., W, Mo) nitride on the surface. The metal nitride can be less susceptible to metal loss, compared to the deposited metal carbon nitride layer.

Exemplary carbon-containing reactants include one or more alkylhydrazines, such as the alkylhydrazines described herein.

Exemplary hydrogen-containing reactants include, for example, hydrogen, a mixture of nitrogen and hydrogen (e.g., about 1 to about 10 or about 10 to about 50 vol % hydrogen), hydrazine, and a derivative thereof, such as a hydrazine derivative described above.

Exemplary metal-containing reactants include one or more metals, such as a Group IV to Group III metal. Specific exemplary metals include titanium, aluminum. The metal-containing reactant can include a halogen-containing reactant as described above. Additionally or alternatively, the metal-containing reactant can include one or more of a metal organic compound reactant and an organometallic compound reactant. By way of examples, the metal-containing reactant can be selected from the group consisting of Group III and Group IV metal organic precursors, such as TDMAT and TMA. By way of particular examples, the metal-containing reactant can include titanium halide (e.g., a reactant comprising titanium and chlorine, such as titanium tetrachloride) or activated species formed therefrom. In at least some cases, the metal-containing reactant(s) can be used to form a thin layer of a metal that forms or can form a native oxide that is less soluble than metal oxide, thereby creating a barrier to metal loss from the deposited metal carbon nitride layer.

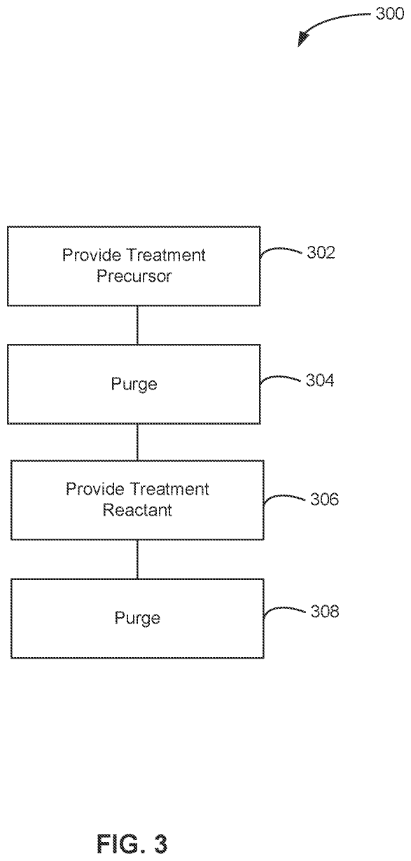

FIG. 3 illustrates a process 300 suitable for step 108 or 110 in accordance with additional examples of the disclosure. In this example, a treatment precursor is provided to the reaction chamber (step 302), a purge is performed (step 304), a treatment reactant is provided to the reaction chamber (step 306), and another purge is performed (step 308). Although described in the context of a treatment, process 300 can be used to form a cap or capping layer. Process 300 can be a thermal process, where a plasma is not used to form excited species. In other cases, process 300 can include forming excited species using, for example, a direct, indirect, or remote plasma.

Process 300 can be used to treat a surface of or underlying the deposited metal carbon nitride and/or to form a capping layer. As noted above, in some cases, method 100 can include both process 200 (step 108) and process 300 (step 110).

Step 302 can be the same or similar to step 202. By way of particular examples, step 302 can include providing one or more metal-containing reactants, such as one or more metal halides, such as one or more of the metal-halogen compounds noted above. The flowrate of the precursor and a duration of step 302 can be the same or similar to the duration and flowrates noted above in connection with step 202.

Steps 304 and 308 can be the same or similar to step 204, described above.

Step 306 can include providing a treatment reactant to react with the precursor or a derivative thereof provided during step 302. A thin film that is less soluble (e.g., in water) than metal oxide may be formed. The thin film can protect the underlying metal carbon nitride layer and thereby mitigate metal loss from the metal carbon nitride layer.

The treatment reactant provided during step 306 can include, for example, one or more of a nitrogen-containing reactant, an oxygen-containing reactant, and a carbon-containing reactant.

Exemplary oxygen-containing reactants can be selected from the group consisting of oxygen, water (H₂O), hydrogen peroxide (H₂O₂), ozone (O₃), or oxides of nitrogen, such as, for example, nitrogen monoxide (NO), nitrous oxide (N₂O), or nitrogen dioxide (NO₂). As further non-limiting examples, the oxygen precursor may comprise: an organic alcohol, such as, for example, isopropyl alcohol, or an oxygen plasma, wherein the oxygen plasma may comprise: atomic oxygen, oxygen radicals, and excited oxygen species.

Exemplary nitrogen-containing reactants and carbon-containing reactants can be the same or similar to the nitrogen-containing reactants and the carbon-containing reactants noted above.

In some cases, where a capping layer is formed during step 110, method 100 can include a step of treating the metal carbon nitride layer using a direct, indirect, or remote plasma formed from a nitrogen containing reactant (e.g., as described above), argon, or a combination thereof.

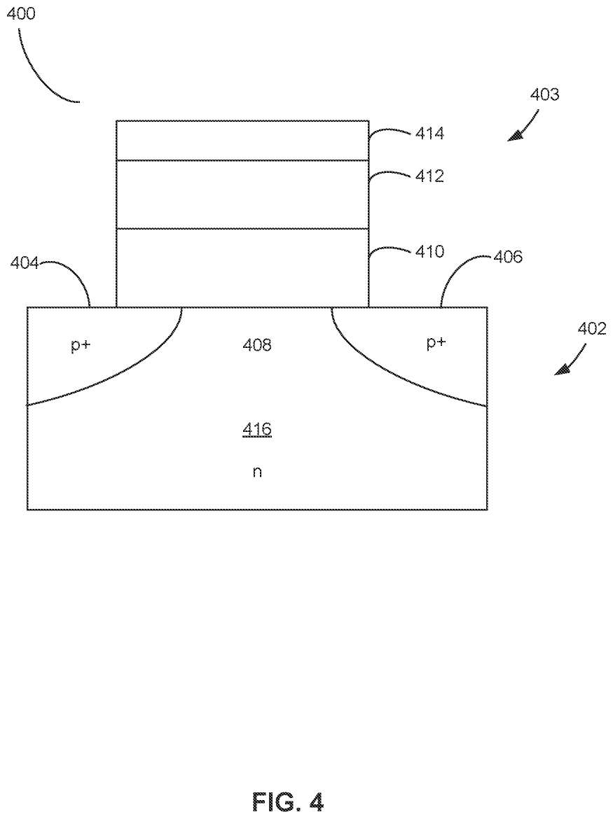

FIG. 4 illustrates a device or structure 400 in accordance with examples of the disclosure. Structure 400 includes a substrate 402, including bulk material 416, and a gate structure 403 overlying substrate 402. As illustrated, substrate 402 includes a source region 404, a drain region 406, and a channel region 408 therebetween. Gate structure 403 includes an electrode 412, i.e., a gate electrode, which may be separated from the channel region 408 by a gate dielectric 410. Gate electrode 412 may comprise a metal carbon nitride layer, including a treated surface and/or cap 414, as described herein. For example, the treated surface can comprise one or more of a halogen, carbon, hydrogen, and a metal, such as titanium or aluminum. By way of particular examples, the treated surface(s) include hydrogen, nitrogen, or a metal. The cap 414 can include, for example, one or more of a metal nitride, a metal carbide, and a metal oxide. The metal nitride, the metal carbide, and the metal oxide can include any metal noted above, such as, for example, titanium, aluminum. By way of further examples, the cap 414 includes a metal oxide or a metal nitride. The cap 414 can have a thickness of greater than 0 to about 1 nm or about 0.5 to about 2 nm.

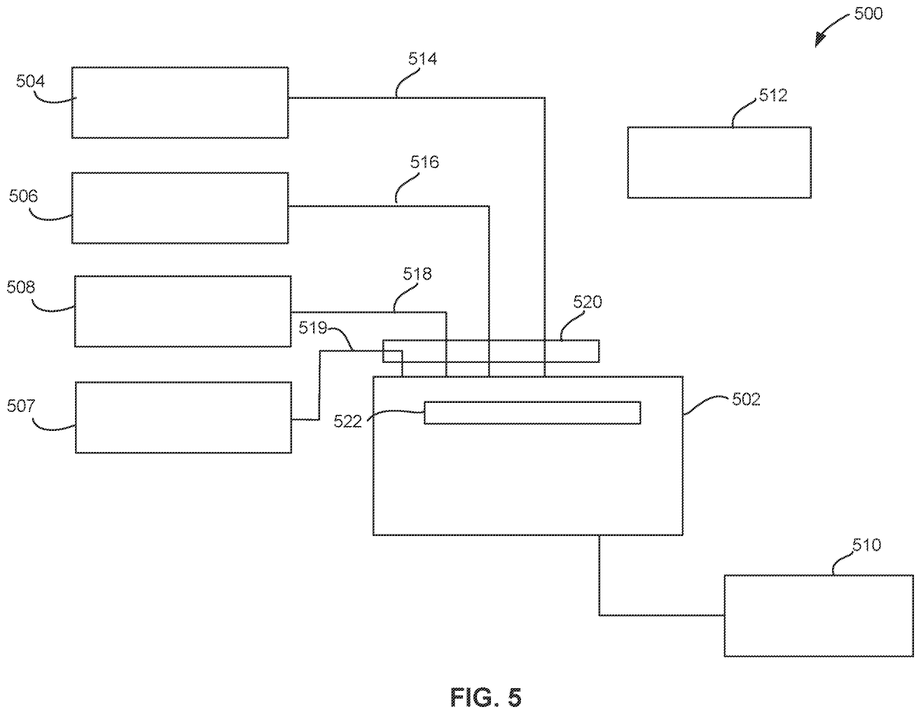

FIG. 5 illustrates a system 500 in accordance with yet additional exemplary embodiments of the disclosure. System 500 can be used to perform a method or process as described herein and/or form a structure or device portion as described herein.

In the illustrated example, system 500 includes one or more reaction chambers 502, a precursor gas source 504, a reactant gas source 506, a treatment and/or reactant source 507, a purge gas source 508, an exhaust source 510, and a controller 512.

Reaction chamber 502 can include any suitable reaction chamber, such as an ALD or CVD reaction chamber. Reaction chamber 502 can be a stand-alone reaction chamber or form part of a process module comprising two or more (e.g., 2-4) reaction chambers.

Precursor gas source 504 can include a vessel and one or more precursors to form a metal (e.g., tungsten, molybdenum) carbon nitride layer, such as the precursors noted above. Reactant gas source 506 can include a vessel and one or more reactants to form the metal carbon nitride layer, such as the reactants noted above. Purge gas source 508 can include a vessel and one or more purge gases, such as a noble gas, nitrogen, or the like.

Treatment precursor/reactant source 507 can include one or more vessels and one or more treatment precursors and/or reactants, such as the treatment precursors and reactants described above. Although illustrated with one source 507, systems in accordance with this disclosure can include two or more (e.g., separate) treatment precursor and reactant sources that each include a vessel and a respective treatment precursor or reactant. More generally, although illustrated with four gas sources 504, 506, 507, and 508, system 500 can include any suitable number of gas sources. Gas sources 504, 506, 507, and 508 can be coupled to reaction chamber 502 via lines 514, 516, 518, and 519, which can each include flow controllers, valves, heaters, and the like.

Exhaust source 510 can include one or more vacuum pumps.

Controller 512 includes electronic circuitry and software to selectively operate valves, manifolds, heaters, pumps and other components included in system 500. Such circuitry and components operate to introduce precursors, reactants, and purge gases from the respective sources 504, 506, 507, and 508. Controller 512 can control timing of gas pulse sequences, temperature of the substrate and/or reaction chamber, pressure within the reaction chamber, and various other operations to provide proper operation of system 500. Controller 512 can include control software to electrically or pneumatically control valves to control flow of precursors, reactants and purge gases into and out of reaction chamber 502. Controller 512 can include modules, such as a software or hardware component, e.g., a FPGA or ASIC, which performs certain tasks. A module can advantageously be configured to reside on the addressable storage medium of the control system and be configured to execute one or more processes.

System 500 can include one or more remote excitation sources 520 and/or direct or indirect excitation sources 522, such as remote and/or direct and/or indirect plasma generation apparatus.

Other configurations of system 500 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 502. Further, as a schematic representation of a system, many components have been omitted for simplicity of illustration, and such components may include, for example, various valves, manifolds, purifiers, heaters, containers, vents, and/or bypasses.

During operation of reactor system 500, substrates, such as semiconductor wafers (not illustrated), are transferred from, e.g., a substrate handling system to reaction chamber 502. Once substrate(s) are transferred to reaction chamber 502, one or more gases from gas sources 504, 506, 507, and 508, such as precursors, reactants, treatment precursors and/or treatment reactants, carrier gases, and/or purge gases, are introduced into reaction chamber 502. In accordance with examples of the disclosure, system 500 can be used to deposit a metal carbon nitride layer and treat and/or cap the metal carbon nitride layer and/or an underlying layer within the same reaction chamber 502.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure comprising a layer of metal carbon nitride (MCN) on a substrate, the method comprising:
providing the substrate within a reaction chamber;
forming a deposited metal carbon nitride layer on the substrate; and
mitigating loss of metal from the deposited metal carbon nitride layer comprising:
forming a treated metal carbon nitride surface comprising:
applying a surface treatment to the deposited metal carbon nitride layer.

2. The method according to claim 1, wherein applying the surface treatment comprises providing an inorganic reactant to the reaction chamber.

3. The method according to claim 1, wherein applying the surface treatment comprises providing one or more of a metal organic compound reactant and an organometallic compound reactant to the reaction chamber.

4. The method according to claim 1, wherein applying the surface treatment comprises providing one or more of a halogen-containing reactant or activated species formed therefrom, a nitrogen-containing reactant or activated species formed therefrom, a carbon-containing reactant or activated species formed therefrom, a hydrogen-containing reactant or activated species formed therefrom, and a metal-containing reactant or activated species formed therefrom, to the reaction chamber.

5. The method according to claim 1, wherein applying the surface treatment comprises providing hydrazine, a derivative thereof, or activated species formed using the hydrazine or the derivative thereof, to the reaction chamber.

6. The method according to claim 1, wherein applying the surface treatment comprises providing one or more of an alkylhydrazine, a dialkylhydrazine, or activated species formed therefrom, to the reaction chamber.

7. The method according to claim 1, wherein applying the surface treatment comprises providing a titanium halide or activated species formed therefrom to the reaction chamber.

8. The method according to claim 7, wherein the titanium halide comprises titanium and chlorine.

9. The method according to claim 1, wherein applying the surface treatment comprises providing one or more of titanium tetrachloride and activated species formed therefrom to the reaction chamber.

10. The method according to claim 1, wherein applying the surface treatment comprises a plasma process.

11. The method according to claim 1, wherein applying the surface treatment comprises one or more cycles of pulsing a metal-containing reactant to the reaction chamber.

12. The method according to claim 11, wherein at least one of the one or more cycles further comprises pulsing one or more of a nitrogen-containing reactant, an oxygen-containing reactant, and a carbon-containing reactant to the reaction chamber.

13. The method according to claim 1, wherein applying the surface treatment further comprises pulsing a nitrogen-containing reactant.

14. The method of claim 1, wherein applying the surface treatment comprises a thermal process.

15. The method of claim 1, wherein a pressure within the reaction chamber during the step of applying the surface treatment is less than 760 torr or is between 0.2 torr and 760 torr.

16. The method of claim 1, wherein applying the surface treatment comprises a soak process.

17. The method of claim 1, wherein the metal is tungsten and the deposited metal carbon nitride layer is a tungsten metal carbon nitride layer.

18. A structure comprising a tungsten carbon nitride (WCN) layer comprising:
a substrate;
a tungsten carbon nitride layer overlying the substrate; and
a treated surface on the tungsten carbon nitride,
wherein the treated surface comprises one or more of a halogen, carbon, hydrogen, nitrogen, and titanium.

19. A device comprising:
a substrate comprising a source region, a drain region, and a channel region;
a layer comprising a tungsten carbon nitride layer overlying the channel region; and
a treated surface overlying the layer comprising tungsten carbon nitride,
wherein the treated surface comprises one or more of a halogen, carbon, hydrogen, nitrogen, and titanium.

20. The device of claim 19, wherein the treated surface comprises titanium.
